(19) United States
(12) Patent Application Publication
(10) Pub. No.: US 2006/0125945 A1
(43) Pub. Date: Jun. 15, 2006

(54) Solid-state imaging device and electronic camera and shading compensaton method

(76) Inventor: Satoshi Suzuki, Tokyo (JP)

Correspondence Address: IPSOLON LLP, 111 SW COLUMBIA, SUITE 710, PORTLAND, OR, 97201, US

(21) Appl. No.: 11/351,081

(22) Filed: Feb. 8, 2006

Related U.S. Application Data
(63) Continuation of application No. 09/924,263, filed on Aug. 7, 2001.

(51) Int. Cl. H04N 5/335

(52) U.S. Cl. 348/311

(57) ABSTRACT

A solid-state imaging device provides an in situ shading correction value regardless of electronic camera performance variation or type of replacement lens installed, etc. In one implementation, light-receiving region 110 of a solid-state imaging device 100 is divided into an effective pixel part 110A and an available pixel part 110B. Pixels 130 in the available pixel part 110B provide output signals indicating the degree of shading at the effective pixel part 110A. Output signals from pixels 130 are used by a control part 220D of the electronic camera for shading correction of image data obtained by the effective pixel part 110A.

### TECHNICAL FIELD

The present invention pertains to a solid-state imaging device and an electronic camera. More specifically, the invention relates to a solid-state imaging device with a large imaging area that can suitably perform shading correction and to an electronic camera incorporating such a solid-state imaging device.

### BACKGROUND AND SUMMARY

Conventionally known solid-state imaging devices for electronic cameras include CCD-type image sensor, CMOS-type image sensor, amplifier-type image sensor, etc. FIG. 21 shows a conventional CCD-type image sensor 10. As shown in the drawing, the CCD-type image sensor 10 consists of a plurality of pixels 12, vertical transfer electrode 13, horizontal transfer electrode 14, and output amp 15 formed on a semiconductor substrate 11. A charge generated by a photodiode (photoelectric conversion element) 12a (FIGS. 22, 23) of pixel 12 passes through the vertical transfer electrode 13, horizontal transfer electrode 14, and output amp 15 and is read outside the CCD-type image sensor 10.

As shown in FIG. 22, at a pixel 12X in about the center of the CCD-type image sensor 10 (near X on a line X-Y in FIG. 21) an incident light ray L11 is received from an installed camera lens and passes through a microlens 12b and color filter 12c and is focused at the center of the photodiode 12a with good efficiency.

On the other hand, as shown in FIG. 23, at a pixel 12Y at the periphery of the CCD-type image sensor 10 (near Y on the line X-Y in FIG. 21), most of an incident light ray L12 misses the photodiode 12a, and its detected luminance is much lower compared to the pixel 12X near X (referred to as luminance shading).

Also, at the periphery of the CCD-type image sensor 10 the incident light ray L12 is incident with a greater slant relative to the pixel 12Y, so the incident light ray L12 is incident more at the edge of the photodiode (photoelectric conversion element) 12a. If this sort of inclination of the incident light ray L12 is large, the signal charge generated by the relevant incident light ray L12 is detected by the photodiodes (photoelectric conversion elements) of other pixels, and crosstalk occurs (referred to as crosstalk shading).

In addition, the refractive index of the microlens 12b is wavelength dependent, so the refractive index is different for each color (e.g., red, green, and blue—R, G, B) of a color filter 12c. This wavelength dependency increases as the angle of incidence of the incident light ray L12 becomes more inclined. As a result, the focusing percentage balance for each color (R, G, B) of the color filter 12c is completely different at the center (near X in FIG. 21) and periphery (near Y) of the light-receiving region 10A of CCD-type image sensor 10, and color balance breakdown occurs (referred to as color shading).

High-performance cameras—particularly the single lens reflex type of electronic camera—need to maintain high sensitivity at each pixel, so the size of the pixels 12 in the built-in CCD-type image sensor 10 is larger than in other camera models. Also, a high-performance electronic camera also needs to have high resolution at the same time, so it has millions of pixels and uses a CCD-type image sensor 10 in which the light-receiving region 10A has a large area.

This sort of increase in the area of the light-receiving region 10A of the CCD-type image sensor 10 increases the inclination of the incident light ray L12 at the periphery of the light-receiving region 10A and makes conspicuous the influences of the various shadings described above.

Recent high-performance electronic cameras that seek to correct the various shadings described above and obtain suitable image data use a shading countermeasure in which the degree to which shading occurs is measured for each camera during manufacture, a shading correction value is found based on this measured value, and this correction value is written to a ROM circuit included in each individual camera.

In finding a shading correction value, first, as shown in FIG. 24, the effective pixel part 15 in the light-receiving region 10A of the CCD-type image sensor 10 is divided into a central region 15A, an intermediate region 15B, and an edge region 15C. Then the luminance (i.e., luminance affected by shading) is found for each region 15A, 15B, and 15C. The effect of shading increases and luminance decreases as distance from the central region 15A increases toward the intermediate region 15B and edge region 15C.

Therefore before an electronic camera is shipped, the degree of shading (luminance) is measured for each region 15A, 15B, and 15C, luminance between the regions 15A, 15B, and 15C is compared, and the comparison results are written to the relevant electronic camera ROM as a correction table. The image data shading is then corrected based on the relevant correction table when the user takes a picture.

As an example, the relative measured value for luminance at the central region 15A may be 100, luminance at the intermediate region 15B may be 80, and luminance at the edge region 15C may be 50. If the luminance at the intermediate region 15B is multiplied 100/80× (multiplication factor 1.2) and the luminance at the edge region 15C is multiplied 100/50× (multiplication factor 2.0) for image data actually obtained at pixels 12 in those regions, it is possible to obtain image data with uniform luminance and shading effects removed across the entire area of the effective pixel part 15.

Nevertheless, various defects can occur in preshipment shading correction as described above. Namely, manufacturing variation occurs between lots and between regions in the semiconductor wafers (i.e., semiconductor substrate 11 in FIG. 21) with which the CCD-type image sensor 10 is made. This wafer manufacturing variation creates slight performance variations in each CCD-type image sensor 10 made of the relevant wafer, so a shading correction value must be found for each electronic camera and this must be written to each ROM.

Also, the multiplication factor (sometimes called a correction sensitivity multiple) found for the intermediate region 15B and the edge region 15C, relative to the central region 15A, has a different value depending on the type of camera lens, its F value, stop value, etc. For example, with the replaceable lens type of single lens reflex electronic camera, a specific camera lens has a multiplication factor of 2× when open and a multiplication factor of 1.1× when the stop value is maximized. If the camera lens is replaced with another camera lens, the multiplication factor may change so that it has, for example, a multiplication factor of 1.5× when open and 1.1× when the stop value is maximized.

For a replaceable lens type of single lens reflex electronic camera it is therefore difficult to obtain a shading correction value (multiplication factor) to be written to a ROM before shipping. Also, the task of writing a correction table based on these correction values (multiplication factors) to a ROM is complicated because that data amount increases.

Also, zoom lenses are included in the camera lenses that can be replaced and mounted on an electronic camera. With this sort of zoom lens, the focal length changes for each image and the shading correction value also changes. The shading correction value also depends on the stop value.

Also, if the subject of correction is widened to luminance shading and color shading in order to increase the performance of an electronic camera, the amount of data written increases, and the required measurement time lengthens, and this leads to an increase in manufacturing cost.

In light of all of these facts pertaining to shading as described above, measuring shading before shipment for each individual electronic camera and finding its correction value greatly increases the data to be written to a ROM and also dramatically increases the manufacturing cost.

In addition, with a replaceable lens type of single lens reflex electronic camera the correction values written to the ROM cannot accommodate new types of replacement camera lens products that are developed after shipment.

Instead of using the above technique to write shading correction values to the ROMs of electronic cameras one by one before shipping, some digital cameras allow a user to take a picture for shading correction using and to find a shading correction value in situ based on the image data obtained at this time. With this technique the user himself prepares a subject that is unpatterned and of uniform luminance, photographs the subject using the electronic camera, and finds the shading correction value. The user must do so every time the lens is replaced, etc., thereby making the electronic camera operation troublesome and is not practical.

The present invention provides a solid-state imaging device that provides in situ shading correction values regardless of performance variation in individual electronic cameras or the type of replaceable lens installed, etc., and provides an electronic camera incorporating such a solid-state imaging device.

In one implementation, a photoelectric conversion element for solving the aforesaid problems is a solid-state imaging device in which multiple pixels with photoelectric conversion elements are disposed in a light-receiving region. Two or more light detection parts capable of outputting a signal indicating the degree of shading are disposed inside or outside the periphery of the light-receiving region. This makes it possible to monitor luminance information (indicating the degree of shading) at multiple positions along the periphery of the light-receiving region, and to find shading correction values in situ.

Moreover, a shading correction value may be determined by comparing luminance information between two or more light detection parts disposed inside or outside along the periphery of the light-receiving region. Such a correction value may be obtained even if the image passing through the camera lens and incident upon the solid-state imaging device has a pattern or does not have uniform luminance or whatever. Regardless of its actual pattern, the image incident upon the solid-state imaging device can be considered to have uniform luminance as if due to a uniform pattern because the image will usually have a circle of least confusion of a few tens of microns, so in the range of at least 2˜4 pixels. Also, if an optical low-pass filter is used at the plane of incidence side of the solid-state imaging device, an image with uniform luminance can be obtained across a wide range, so a suitable shading correction value can always be obtained regardless of whether or not the subject has a pattern, or uniform illumination, etc.

Also, the light-receiving region of the solid-state imaging device may be divided into an effective pixel part, where the relevant photoelectric conversion element output signals are used for image generation, and an available pixel part, where the relevant photoelectric conversion element output signals are not used for image generation. The photoelectric conversion elements of the pixels included in the available pixel part are used as the light detection parts. This makes it possible to perform shading correction on image data obtained at the effective pixel part based on the signal from the available pixel part.

Also, the solid-state imaging device may separately include a first output part for reading output signals from pixels in the effective pixel part and a second output part for reading output signals from pixels in the available pixel part. Through this it is possible to immediately obtain the data needed for finding the shading correction value.

Also, the solid-state imaging may include a light-shielding film having a specific aperture formed at the plane of incidence side of the available pixel part, the center of the specific aperture being offset by a distance that is predetermined for each pixel from the center of a selected photoelectric conversion element. This makes it possible to compare luminance information between pixels at the light detection part after the light has been shielded by multiple light-shielding films, and makes it possible to find where on the photodiodes (photoelectric conversion elements) light is incident. Also, it is possible to find any slant in the angle of incidence of an incident light ray, and to use this result to find a shading correction value in situ.

Also, the solid-state imaging device may include a microlens disposed at each pixel at the plane of incidence of photoelectric conversion elements in the light-receiving region. The microlenses of the available pixel part may be disposed so that their optical axes are offset by a fixed distance that is predetermined for each pixel from the center of the relevant or selected photoelectric conversion element. This makes it possible to compare luminance information between pixels at multiple light detection parts with different microlens positions, and it is possible to find where on the photodiodes (photoelectric conversion elements) light is incident. Also, it is possible to find any slant to the angle of incidence of an incident light ray, and to use this result to find a shading correction value in situ.

Also, the solid-state imaging device may include a reference pixel that is in the available pixel part and does not have a microlens. This makes it possible to compare the luminance signal from a light detection part with pixels having microlenses to the luminance signal from a light detection part with pixels not having microlenses, thereby allowing a more accurate correction value to be obtained.

Also, the solid-state imaging device may include a multiple types of color filters that are disposed at pixels in the available pixel part, and a signal may be output from the light detection part indicating the degree of shading at a pixel where a specific color filter is disposed. This makes it possible to find a shading correction value corresponding to the characteristics of each color filter.

Also, an electronic camera described may be equipped with any of these solid-state imaging device. Such a camera may include an image adjustment means for adjusting image data based on the aforesaid signal indicating the degree of shading. The electronic camera may be a replaceable lens type of single lens reflex electronic camera. Therefore the amount of correction while taking a picture can be suitably determined based on the signal from the light detection part of the solid-state imaging device. Shading correction may be performed using a transmissivity control film such as an EC film, etc. while taking a picture, so the picture is taken with the transmissivity of the transmissivity control film controlled at the effective pixel part surface so as to produce the optimum illuminance profile. Alternatively, shading correction may be performed by applying this correction value to image data obtained by taking a picture. Or both may be combined. As a result, it is not necessary to measure the shading correction value for each individual camera before shipment and write the correction to a ROM. This provides an electronic camera that is excellent in both cost and performance.

Additional objects and advantages of the present invention will be apparent from the detailed description of the preferred embodiment thereof, which proceeds with reference to the accompanying drawings.

### BRIEF DESCRIPTION OF THE DRAWINGS

FIG. 1 is a plan view of a solid-state imaging device (CCD) of a first embodiment.

FIG. 2 is a block diagram showing a control part of an electronic camera of the first embodiment.

FIG. 3 is a plan view of a solid-state imaging device (CCD) of a second embodiment.

FIG. 4 is a plan view showing a light-shielding film aperture of an available pixel part in the solid-state imaging device (CCD) of the second embodiment.

FIG. 5 is a vertical sectional view showing the light-shielding film aperture of the available pixel part in the solid-state imaging device (CCD) of the second embodiment.

FIG. 6 includes drawings explaining luminance information at the available pixel part in the solid-state imaging device (CCD) of the second embodiment.

FIG. 7 is a plan view of a solid-state imaging device (CCD) of a third embodiment.

FIG. 8 is a plan view showing positions of microlenses at the available pixel part in the solid-state imaging device (CCD) of the third embodiment.

FIG. 9 is a vertical sectional view showing positions of microlenses at the available pixel part in the solid-state imaging device (CCD) of the third embodiment.

FIG. 10 includes drawings explaining luminance information at the available pixel part in the solid-state imaging device (CCD) of the third embodiment.

FIG. 11 is a plan view showing positions of microlenses at an available pixel part in a solid-state imaging device (CCD) of a fourth embodiment.

FIG. 12 is a vertical sectional view showing positions of microlenses of the available pixel part of the fourth embodiment.

FIG. 13 includes drawings explaining luminance information of the available pixel part of the fourth embodiment.

FIG. 14 is a vertical sectional view showing positions of microlenses when finding a shading correction value for each color filter.

FIG. 15 is a plan view of a solid-state imaging device (CCD) of a fifth embodiment.

FIG. 16 is a block diagram showing a control part of an electronic camera of the fifth embodiment.

FIG. 17 is a plan view showing a light-shielding film aperture of an available pixel part in the solid-state imaging device (CCD) of the sixth embodiment.

FIG. 18 includes drawings explaining luminance information at the available pixel part in the solid-state imaging device (CCD) of the sixth embodiment.

FIG. 19 is a drawing showing an overall structure of a single lens reflex digital camera equipped with a CCD (solid-state imaging device).

FIG. 20 is a correction flow diagram showing image processing performed at the electronic camera side.

FIG. 21 is a plan view of a conventional CCD (solid-state imaging device).

FIG. 22 is a vertical sectional view showing shading in a conventional CCD (solid-state imaging device).

FIG. 23 is a vertical sectional view showing shading in a conventional CCD (solid-state imaging device).

FIG. 24 is a plan view of a conventional CCD (solid-state imaging device).

### DETAILED DESCRIPTION OF PREFERRED EMBODIMENT

### First Embodiment

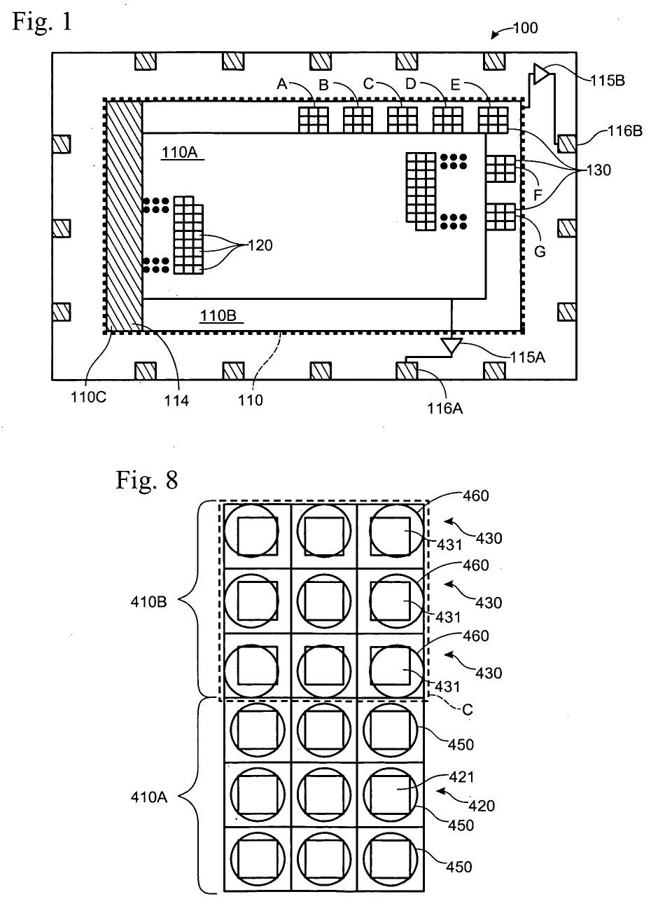

FIG. 1 is a drawing showing the overall structure of a solid-state imaging device 100 in accordance with a first embodiment. The solid-state imaging device 100 has a light-receiving region 110 (in the drawing, indicated by a thick broken line) having a central part that is an effective pixel part 110A and an available pixel part 110B surrounding the effective pixel part 110A. “Available pixel (part)” is generally defined as a concept that includes “effective pixel (part),” but in this application, “available pixel part” is defined for convenience as the “light-receiving region” excluding the “effective pixel part.”

Also, an optical black region 110C for measuring dark current is provided near the effective pixel part 110A (at the left side in FIG. 1). This optical black region 110C is formed of pixels (not shown in the drawing) with the same structure as those in the effective pixel part 110A, and the plane of incidence of photodiodes (photoelectric conversion elements) included in these pixels is completely shielded by a light-shielding film 114. The pixels of the optical black region 110C provide a signal indicating noise components such as dark current, etc.

Many pixels 120 are provided in the effective pixel part 110A, and image data imaged by the electronic camera is generated using the output signals (pixel data) from these pixels 120. The available pixel part 110B is provided along and inside periphery (in the drawing, indicated by a thick broken line) of the light-receiving region 110. Pixels 130 (the light detection part) of this available pixel part 110B are distant from the center of the light-receiving region 110, so great variation can be expected in the characteristics of each pixel in the manufacturing process, and their output signals are not used to generate image data.

However, some pixels 130 that are of the available pixel part 110B and are in a margin area adjacent to the effective pixel part 110A can generate a signal of high reliability, analogous to the signal of pixels 120 in the effective pixel part 110A. Therefore, in this first embodiment, the output signals from pixels 130 in the available pixel part 110B near the effective pixel part 110A are used as signals indicating the degree of shading occurring in image data obtained from pixels 120 in the effective pixel part 110A, and shading correction is performed. A plurality of blocks (A-G in the example in the drawing) are provided in the available pixel part 110B, each block with multiple pixels 130 (e.g., a 3×3 block of pixels, a 5×5 block if pixels, etc.).

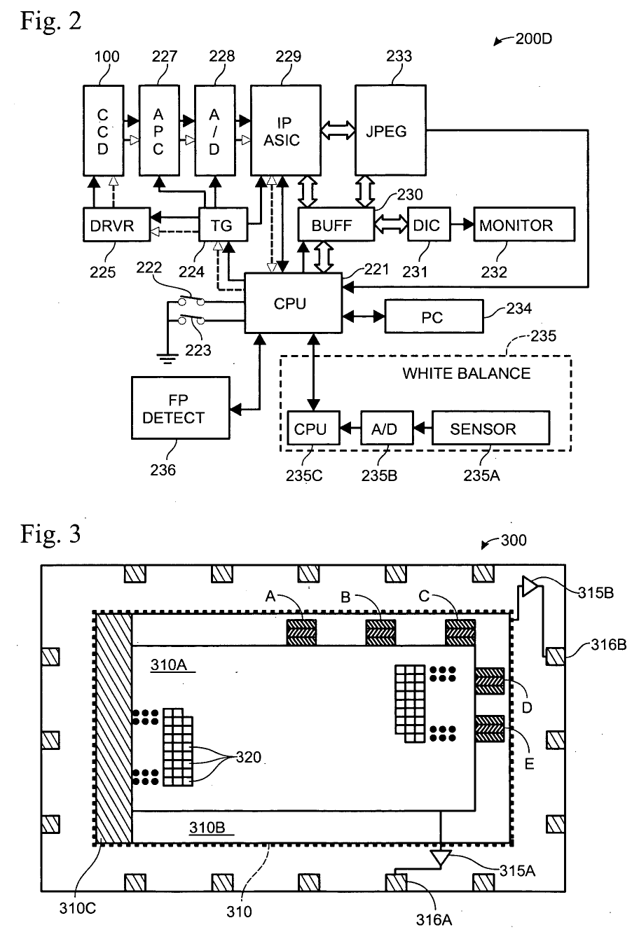

Solid-state imaging device 100 has formed on it an output amplifier 115A for amplifying and reading the output signals (voltage) of each pixel 120 in the effective pixel part 110A and a pad electrode 116A for externally outputting signals indicating image data. Also, an output amplifier 115B for each pixel 130 in the available pixel part 110B and a pad electrode 116B are formed separately from amplifier 115A and pad electrode 116A. By thus providing the output amp 115B separate from the output amp 115A, the output signal from the available pixel part 110B indicating shading can be quickly read externally, such as by an analog signal processing circuit 227 (FIG. 2), thereby shortening the processing time needed for shading correction.

Consider an exemplary instance of finding a correction value for shading in the horizontal direction of the light-receiving region 110 in which the average outputs at each block A, B, C, D, and E in the available pixel part 110B are 10:9:8:6:4. Shading is corrected by multiplying the image data (raw data) obtained as the result of taking a picture by the multiplication factors (correction sensitivity multiples) 1:10/9:10/8:10/6:10/4 along the horizontal direction from the center to the edge. The result is that image data with uniform luminance can be obtained using the entirety of the effective pixel part 110A.

Furthermore, by modifying the multiplication factors (correction sensitivity multiples) to values smaller than the ratios noted above, it is possible to deliberately cause luminance variation that is about the same as shading in silver chloride photography. As a result, it is possible to obtain photographs similar to silver chloride photographs.

Also, shading correction in the vertical direction of the light-receiving region 110 may be accomplished by reading the average output signals of the pixels 130 of blocks E, F, and G and performing the same sort of processing.

Furthermore, if a CCD-type image sensor is used as the solid-state imaging device 100, the output signals of each pixel 130 in each block A, B, C, D, and E of the available pixel part 110B can be read at high speed by partial reading (i.e., reading separately from the two output amps 115A and 115B). If a [C]MOS-type image sensor is used as the solid-state imaging device 100, random access is possible. For a [C]MOS-type image sensor, the output signals of each pixel 130 in each block A, B, C, D, and E of the available pixel part 110B can easily be read locally, and the relevant output signals indicating the shading amount can be read at high speed.

FIG. 2 is a block diagram of the structure of an electronic camera control part 200D that performs image data generation and shading correction using the respective output signals (image data) from the effective pixel part 110A and available pixel part 110B of the solid-state imaging device 100.

A CPU 221 oversees various types of operations and controls in the electronic camera receives input of a half-depression signal and a full-depression signal from a half-depression switch 222 and a full-depression switch 223 linked to a release button. In practice, when the half-depression switch 222 is turned on and a half-depression signal is input, a focal point detection device 236 detects the focus detection status of imaging lens 831 (see FIG. 19) according to instructions from the CPU 221, and drives the imaging lens 831 to the desired focus position.

The CPU 221 drives the solid-state imaging device (CCD) 100 via a timing generator (TG) 224 and a driver 225 according to the aforesaid half-depression signal input. The timing generator 224 controls the operation timing of analog processing circuit 227, analog-to-digital (A/D) conversion circuit 228, and image processing circuit 229 (implemented as an application specific integrated circuit, ASIC, for example. Meanwhile, the CPU 221 starts driving a white balance detection processing circuit 235.

After the half-depression switch 222 is on (closed), then the full-depression switch 223 is turned on (closed), the CPU 221 moves a quick turn mirror 811 (FIG. 19) using a driving means not shown in FIG. 2. When this happens, subject light from the imaging lens 831 is focused on the plane of incidence of the solid-state imaging device (CCD) 100, and signal charges corresponding to subject image brightness accumulate in the pixels 120 and 130 of the solid-state imaging device (CCD) 100.

The signal charges accumulated in the pixels 120 and 130 of the solid-state imaging device (CCD) 100 are output by separate output amps 115A and 115B (FIG. 1) according to timing created by drive pulses from the driver 225, and are input to the analog signal processing circuit 227, which includes an automatic gain control (AGC) circuit or correlated double sampling (CDS) circuit, etc.

The analog signal processing circuit 227 performs analog processing such as gain control, noise elimination, etc., on the analog image signal from the CCD 100. Having been analog processed in this way, the signal is converted to a digital image signal by the A/D conversion circuit 228 and then introduced to an image processing circuit (for example, an ASIC) 229.

The image processing circuit 229 performs various types of image preprocessing (for example, shading correction, white balance adjustment, contour compensation, gamma correction, etc.) on the input digital image signal based on data for image processing stored in a memory 230. In this embodiment the image processing circuit 229 functions as an image adjustment means. Furthermore, white balance adjustment by the aforesaid image processing circuit 229 is performed based on a signal from the white balance detection processing circuit 235 connected to the CPU 221.

The white balance detection processing circuit 235 includes a white balance sensor (color temperature sensor) 235A, an A/D conversion circuit 235B that converts the analog signal from the white balance sensor 235A to a digital signal, and a CPU 235C that generates a white balance adjustment signal based on the digitized color temperature signal. Of these, the white balance sensor 235A includes multiple photodiodes (photoelectric conversion elements) having respective sensitivities to red (R), blue (B), and green (G), and receives a light image for the entire field of view. Also, the CPU 235C in the white balance detection processing circuit 235 calculates R gain and B gain based on the output signal from the solid-state imaging device (CCD) 100. The calculated gains are sent to and stored in specified registers of the CPU 221 and used for white balance adjustment by the image processing circuit 229.

The image processing circuit 229 performs processing to convert image data that has undergone the various types of image preprocessing described above into a data format suitable for JPEG-type data compression, and after this image post-processing has been performed the relevant image data is temporarily stored in the buffer memory 230.

Furthermore, the image processing circuit 229 exchanges adjustment data (for example, the scale factor) with the relevant compression circuit 233 so that the specified amount of compression is obtained when image data is compressed in the compression circuit (JPEG) 233, which will be described later.

Image data from the image processing circuit 229 stored in the buffer memory 230 is sent to the compression circuit 233. The compression circuit 233 compresses (data compresses) the aforesaid image data by the compression amount specified in the JPEG format using data for compression stored in the buffer memory 230. The compressed image data is sent to the CPU 221 and is recorded on a storage medium (for example, a PC card) 234 such as a flash memory connected to the CPU 221.

Meanwhile, image data (uncompressed data) that has undergone image processing (preprocessing, postprocessing) by the image processing circuit 229 and been stored in the buffer memory 230 is converted to a data format suitable for display by a display image creation circuit 231 and displayed on an external monitor 232 such as an LCD, etc. (displaying the imaging results).

In this first embodiment electronic camera, the output signal from the effective pixel part 110A (in the drawing, the black arrow) of the solid-state imaging device (CCD) 100 and the output signal from the available pixel part 110B (in the drawing, the white arrow) are output to the analog processing circuit 227, A/D conversion circuit 228, and image processing circuit (for example, an ASIC) 229 by separate systems, thereby allowing the time for subsequent image processing such as shading correction, etc. to be shortened.

As indicated by the broken-line arrows in FIG. 2, the output signal obtained for shading correction may be fed back to the solid-state imaging device (CCD) 100 to drive and control the solid-state imaging device (CCD) 100.

As described above, the shading correction value in this first embodiment is based on the signals from the pixels 130 of the available pixel part 110B. Alternatively, the shading correction value based on the pixels 120 of the effective pixel part 110A near the available pixel part 110B.

### Second Embodiment

FIGS. 3-6 illustrate as a second embodiment a solid-state imaging device 300 which differs from the first embodiment in that a light-shielding film 332 having apertures 332a is formed at the plane of incidence of pixels 330 in an available pixel part 310B.

As shown in FIG. 3, the light-receiving region 310 is divided into an effective pixel part 310A and an available pixel part 310B. An optical black region 310C for measuring dark current is provided at a location near the effective pixel part 310A (at the left side in FIG. 3). Also, output amps 315A and 315B and pad electrodes 316A and 316B are formed outside the periphery (in the drawing, indicated by a thick broken line) of the light-receiving region 310. Output amps 315A and 315B amplify the output signals (voltage) of each of pixels 320 and 330 in the effective pixel part 310A and available pixel part 310B, respectively, and pad electrodes 316A and 316B allow the output signals to be read.

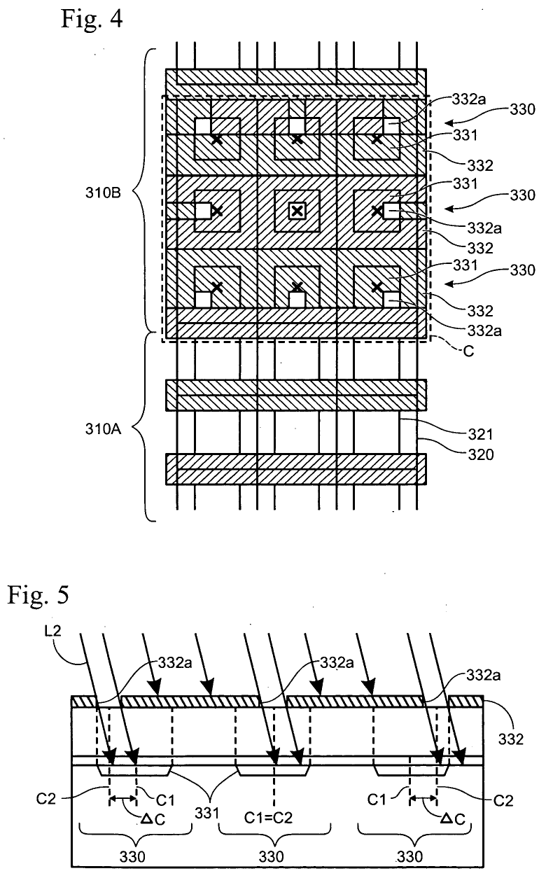

The available pixel part 310B is provided along and inside the periphery (in the drawing, indicated by a thick broken line) of the light-receiving region 310. Pixels 330 of the available pixel part 310B are arranged in 3×3 pixel groups, for example, as shown in FIGS. 3 and 4, to form blocks A, B, C, D, and E. As shown in FIG. 3, these blocks A, B, C, D, and E are disposed so that blocks A, B, and C are at the top side of the available pixel part 310B and blocks D and E are at the right side and they bound the effective pixel part 310A.

As shown in FIGS. 4 and 5, apertures 332a in the light-shielding film 332 are formed at the plane of incidence of pixels 330 in each block A, B, C, D, and E. The center of the aperture 332a for each pixel is separated from the center (indicated by X in FIG. 4) of the photodiode (photoelectric conversion element) 331 by a predetermined distance according to the position of the pixel in the block.

As shown in FIG. 5, centers C2 of some apertures 332a of the light-shielding film 332 formed at the upper surface of the photodiodes 331 are offset by a fixed relationship (ΔC) relative to center C1 of photodiodes 331. As a result, the amount of light incident upon the photodiodes 331 changes according to the offset amounts of the apertures 332a and the angle of incidence of the incident light ray L2. Furthermore, offset amount ΔC is determined for each individual pixel, and is “0” at the center of a block.

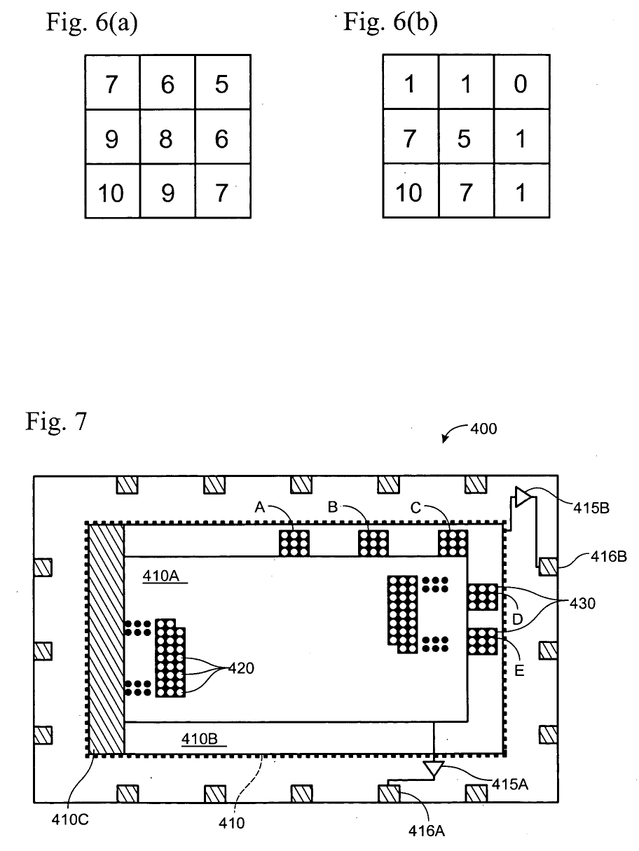

FIG. 6(a) illustrates the luminance at the 3×3 pixels of block C (FIG. 3) when a first exemplary replaceable camera lens is installed. In this illustration, the camera lens has an incident light ray angle of incidence that is comparatively close to vertical (for example, Nikon's Nikkor 105 mm; F8). In contrast, FIG. 6(b) illustrates the luminance at the 3×3 pixels of block C for another replaceable camera lens, such as Nikon's Nikkor 50 mm; F1.4S, having a relatively short focal length, the aperture stop is opened, and an incident light ray angle of incidence is slanted to the horizontal side.

Thus, when replaceable camera lenses with different focal lengths and F values are installed, and the aperture stops are different, different values (luminance) can be obtained for each pixel in block C. In FIG. 6(a) the average output is about 7.44 and the difference in output between the lower left pixel and the upper right pixel is 5. In FIG. 6(b) the average output is about 3.66, which is small, and the difference in output between the lower left pixel and the upper right pixel is 10, which is large.

Block C is located at the upper right side at the periphery of the light-receiving region so at that position the smaller the average output, or the larger the difference in output between the lower left pixel and the upper right pixel, correspond to the greater degree of slant of incident light. As a means of correction, a correction value may be found directly from values such as the average output, or the output difference, or the like, of each block, or a preset correction value may be applied. To find the correction value directly, the amount of luminance decrease of a pixel part near each block location is estimated from values (average output, output difference) at each location in each block A, B, and C, and a luminance shading correction value (multiplication factor) is determined for pixel parts at each location. If an optimum luminance shading correction value (multiplication factor) is found in advance through image evaluation for each block value, and a table is created and that data is written to a ROM, etc., in the camera before shipment, a more accurate luminance shading correction value (multiplication factor) can be used.

This sort of shading correction value is found for each individual block A, B, C, D, and E.

### Third Embodiment

FIGS. 7-10 illustrate as a third embodiment a solid-state imaging device 400 which differs from the first embodiment in that microlenses 450 are disposed at the plane of incidence of pixels 420 in the effective pixel part 410A provided in the light-receiving region 410, and microlenses 460 are disposed at the plane of incidence of pixels 430 in the available pixel part 410B.

As shown in FIG. 7, the light-receiving region 410 of solid-state imaging device 400 is divided into an effective pixel part 410A and an available pixel part 410B. An optical black region 410C for measuring dark current is provided at the left side of the effective pixel part 410A in FIG. 7.

Also, output amps 415A and 415B and pad electrodes 416A and 416B are formed outside the periphery (in the drawing, indicated by a thick broken line) of the light-receiving region 410. Output amps 415A and 415B amplify the output signals (voltage) of each of pixels 420 and 430 in the effective pixel part 410A and available pixel part 410B, respectively, and pad electrodes 416A and 416B allow the output signals to be read.

The available pixel part 410B is provided inside the periphery (in the drawing, indicated by a thick broken line) of the light-receiving region 410. Pixels 430 of the available pixel part 410B are arranged in 3×3 pixel groups, for example, as shown in FIGS. 7 and 8, to form blocks A, B, C, D, and E. As shown in FIG. 7, these blocks A, B, C, D, and E are disposed so that blocks A, B, and C are at the top side of the available pixel part 410B and blocks D and E are at the right side and they bound the effective pixel part 410A. Also, microlenses 460 are formed, as shown in FIGS. 8 9, at each block A, B, C, D, and E so that each optical axis (center) C11 has a fixed relationship with the center C12 of photodiodes (photoelectric conversion elements) 431.

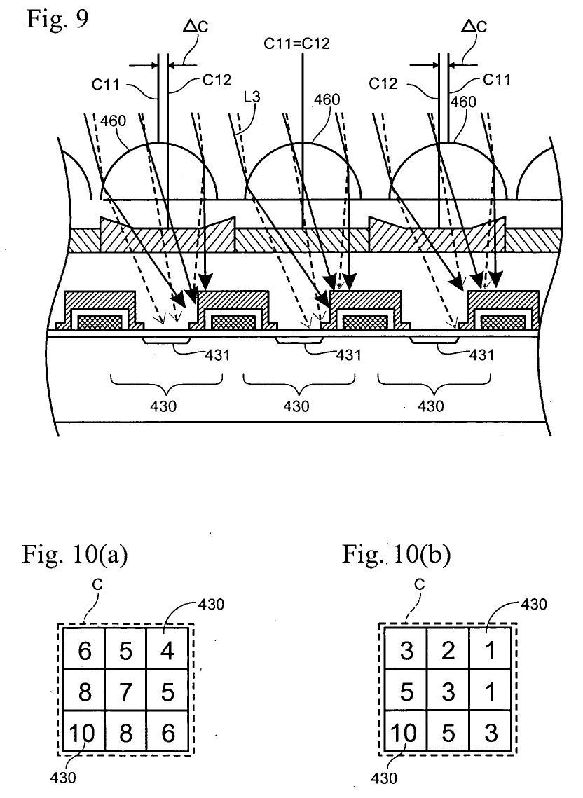

The optical axes (center) C11 of some microlenses 460 formed at the upper surface of the photodiodes 431 are offset by a fixed relationship (ΔC) relative to the centers C12 of the photodiodes 431. As a result, the amount of light incident upon the photodiodes 431 changes according to the offset amount between the optical axis (center) C11 of the microlens 460 and center C12, and the angle of incidence of incident light ray L3 (FIG. 9). Also, the value of ΔC is predetermined for each individual pixel.

FIG. 10(a) illustrates the luminance at the 3×3 pixels of block C (FIG. 7) when an installed replaceable camera lens has an incident light ray angle of incidence that is comparatively close to vertical (for example, Nikon's Nikkor 105 mm; F8), and the aperture stop is narrowed. ON the other hand, FIG. 10(b) illustrates the luminance at the 3×3 pixels of block C (FIG. 7) when an installed replaceable camera lens has an incident light ray angle of incidence that is slanted to the horizontal side (for example, Nikon's Nikkor 50 mm; F1.4S), a relatively short focal length, and the aperture stop is opened.

Thus when replaceable camera lenses with different focal lengths and F values are installed, and the aperture stops are different, different values (luminance) obtained for each pixel in block C. In FIG. 10(a) the average output is about 6.55 and the difference in output between the lower left pixel and the upper right pixel is 6. In FIG. 10(b) the average output is about 3.66, which is small, and the difference in output between the lower left pixel and the upper right pixel is 9, which is large.

Block C is located at the upper right side at the periphery of the light-receiving region, so at that position the smaller the average output, or the larger the difference in output between the lower left pixel and the upper right pixel, correspond to the greater degree of slant of incident light. As a means of correction, a correction value may be found directly from values such as the average output or the output difference, or the like, of each block; or a preset correction value may be applied. To find the correction value directly, the amount of luminance decrease of a pixel part near each block location is estimated from values (average output, output difference) at each location in each block A, B, and C, and a luminance shading correction value (multiplication factor) is determined for pixel parts at each location. If an optimum luminance shading correction value (multiplication factor) is found in advance through image evaluation for each block value, and a table is created and that data is written to a ROM, etc., before shipment, a more accurate luminance shading correction value (multiplication factor) can be used.

According to the solid-state imaging device 400 of this embodiment, the optical axis of the microlens 460 at each pixel 430 in a unit (block) of 3×3 pixels, for example, is different with regard to the center position of the photodiodes 431. The amount of light incident upon photodiodes 431 of each pixel 430 can be changed even when the angle of incidence of the incident light ray L3 is the same, and based on this result it is possible to find a correction value (multiplication factor) for shading.

### Fourth Embodiment

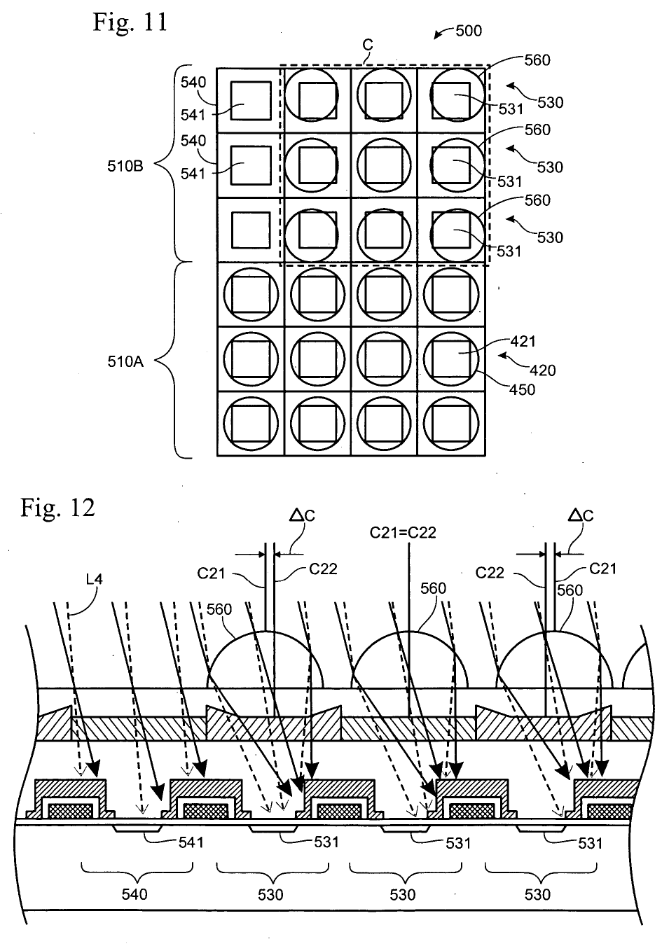

FIGS. 11-13 illustrate as a fourth embodiment a solid-state imaging device 500 which differs from the third embodiment in that reference pixels 540 that do not have a microlens are provided at the available pixel part 510B, while microlenses 560 are formed at the plane of incidence of pixels 530 at the available pixel part 510B. Otherwise the structure of the solid-state imaging device 500 is the same as the solid-state imaging device 400 of the third embodiment, and redundant explanation of imaging device 500 shall be omitted.

As shown in FIG. 11 and FIG. 12, the optical axes (centers) C21 of the microlenses 560 of available pixel part 510B of the fourth embodiment are formed so that they are offset exactly by fixed distances from the centers C22 of photodiodes (photoelectric conversion elements) 531.

In accordance with the solid-state imaging device 500 of this fourth embodiment, the optical axes (centers) C21 of microlenses 560 formed at the planes of incidence of the pixels 530 are offset by ΔC relative to the centers C22 of photodiodes 531, so the amount of light incident upon the photodiodes 531 changes according to the offset amount ΔC and the incident light ray angle of incidence (FIG. 12). Here too offset amount ΔC is a distance that is predetermined for each individual pixel.

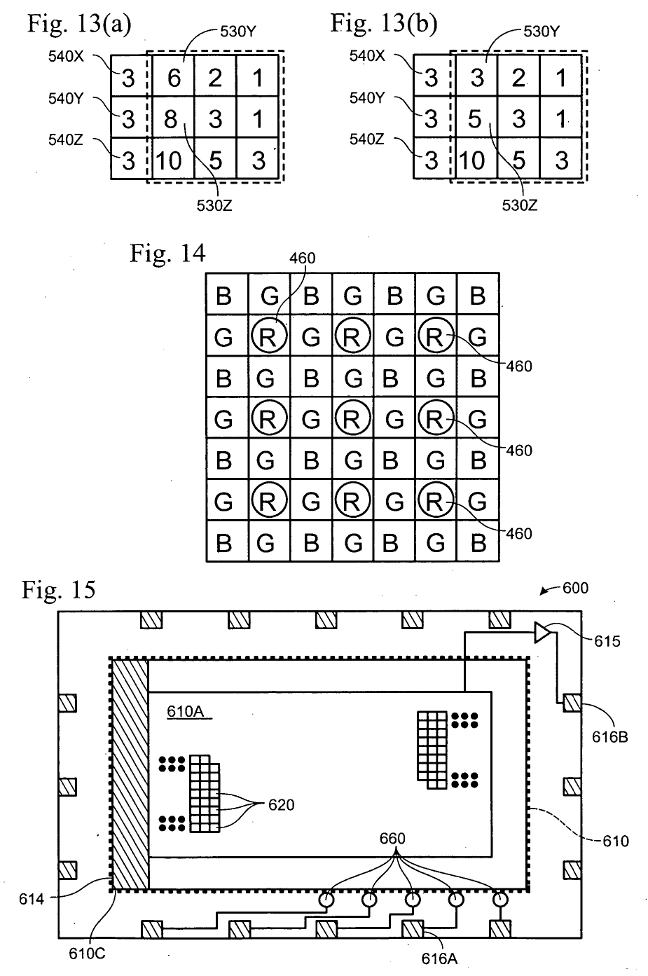

When a different replaceable camera lens is used with the solid-state imaging device 500 or the aperture stop value is different, luminance changes at the pixels 530 provided in the available pixel part 510B (for example, pixels 530Y and 530Z in FIGS. 13(a) and (b)). However, reference pixels 540 have very little dependency on the incident light ray angle of incidence, and there are almost no luminance changes at pixels 540X, 540Y, and 540Z in FIGS. 13(a) and (b), for example.

Thus, the output signals from the reference pixels 540 depend very little on the angle of incidence and also have little camera lens dependency. As a result, the output signals of pixels (monitor pixels) in each block A, B, C, D, and E can be quantitatively found with this output signal (voltage) as the reference voltage.

Furthermore, since the third and fourth embodiments are highly dependent on the wavelength of the incident light because of the microlenses 460 and 560 (the incident light rays indicated by solid lines and the incident light rays indicated by broken lines in FIG. 9 and FIG. 12), a shading correction value (color shading correction value) may be found for each type of color filter (for example, R, G, B) provided at the pixels 430 and 530. In this case, as shown in FIG. 14, the microlens 460 offset amount ΔC is determined and the shading correction value is found by focusing only on pixels 530 provided with a specific color filter (R in the example shown in the drawing).

### Fifth Embodiment

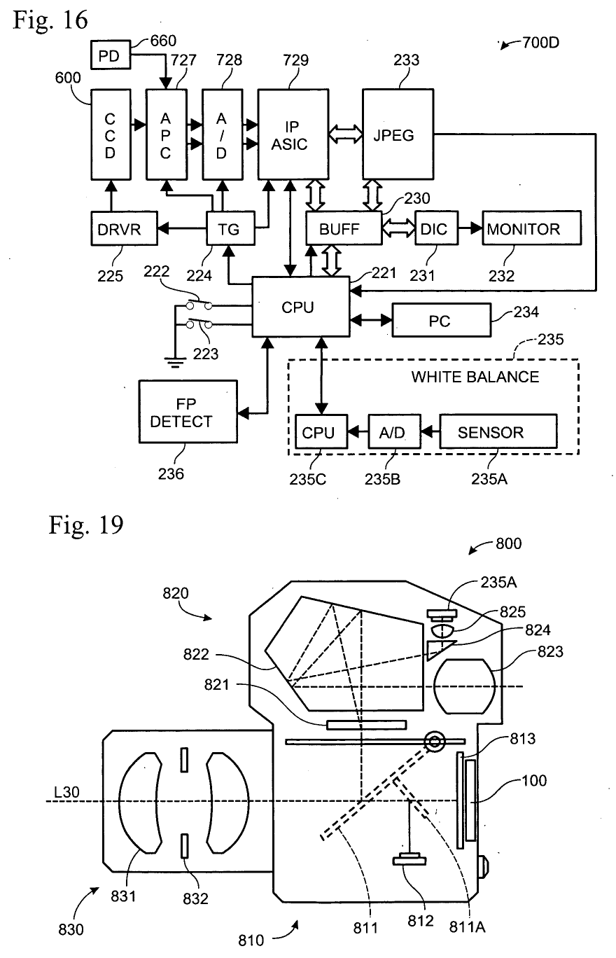

FIG. 15 and FIG. 16 illustrate as a fifth embodiment a solid-state imaging device 600 which differs from the first embodiment in that light sensors 660 are disposed outside the periphery (in the drawing, indicated by a thick broken line) of the light-receiving region 610.

An output amp 615 and pad electrode 616B are included for respectively amplifying and reading the output voltage of each pixel 620 and 630 in the effective pixel part 610A and available pixel part 610B. In addition, a pad electrode 616A for outputting signals from light sensors 660 is formed outside the periphery (in the drawing, indicated by a thick broken line) of the light-receiving region 610 of this solid-state imaging device 600.

The light sensors 660 are disposed at a fixed separation, as shown in FIG. 15, from the outside periphery (in the drawing, indicated by a thick broken line) of the light-receiving region 610. This makes it possible to monitor the decrease in luminance that occurs due to shading at pixels 620 of the effective pixel part 610A based on the output signal from the light sensors 660.

If the ratio of the output signals from the light sensors 660 disposed along the outside periphery (in the drawing, indicated by a thick broken line) of the light-receiving region 610 is for example 10:9:8:6:4 from the center to the right edge, shading is corrected by multiplying the image data obtained from pixels 620 of the effective pixel part 610A by the multiplication factors (sensitivity multiples) 1:10/9:10/8:10/6:10/4 along the horizontal direction from the center to the edge. Thus, image data unaffected by shading can be obtained within the effective pixel part 610A.

Furthermore, the implementation above includes light sensors 660 that are disposed along the horizontal direction of the effective pixel part 610A. It is also possible to dispose the light sensors 660 in the vertical direction of the effective pixel part 610A and use those output signals for shading correction.

FIG. 16 is a block diagram for explaining the structure of an electronic camera control part 700D that performs shading correction using the output signals from the light sensors 660 of the solid-state imaging device 600. This electronic camera control part 700D differs from the first embodiment control part 200D (FIG. 2) only in the signal processing system for shading correction.

The output signals (image data) from pixels 620 in the solid-state imaging device (CCD) 600 and the output signals from the light sensors 660 are input to the analog signal processing circuit 727 by separate systems. The output signals (image data) from the solid-state imaging device (CCD) 600 and the output signals from the light sensors 660 processed by the analog signal processing circuit 727 are additionally introduced to the A/D conversion circuit 728 and image processing circuit 729, and undergo image preprocessing such as white balance adjustment, contour compensation, gamma correction, etc. at the image processing circuit 729. In this embodiment the image processing circuit 729 functions as an image adjustment means. Furthermore, the remaining structure of the control part 700D is the same as the first embodiment control part 200D (FIG. 2), so corresponding elements are assigned the same codes and repeated detailed explanation thereof is omitted.

### Sixth Embodiment

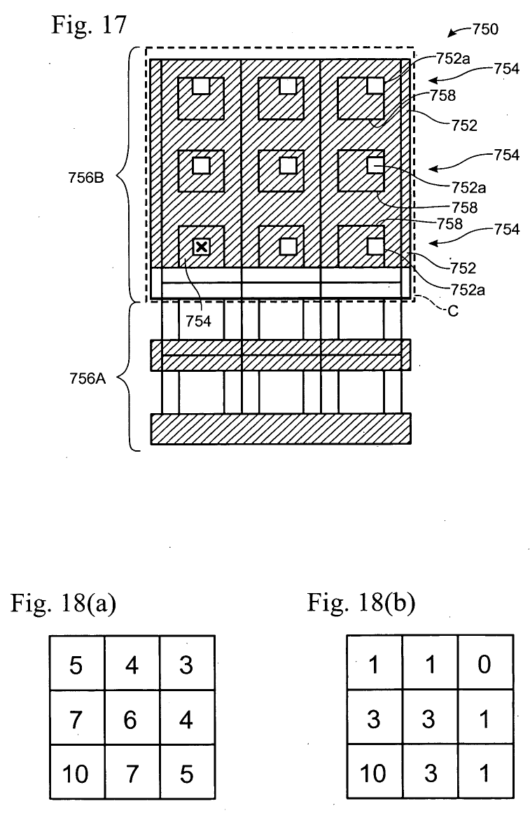

FIG. 17 is a plan view illustrating as a sixth embodiment a solid-state imaging device 750 having a light-shielding film 752 with apertures 752a that are formed at the plane of incidence of pixels 754 in an available pixel part 756B for a monitor pixel C. Solid-state imaging device 750 of the sixth embodiment differs from the second embodiment (FIG. 4) in that the aperture 752a in the light-shielding film 752 at the lower left pixel 754 is positioned at the center of photodiode 758. The positions of apertures 752a in the light-shielding film 752 are gradually offset upward and to the right for pixels above and to the right of lower left pixel 754, respectively.

In this embodiment, the center position of the light-receiving part of solid-state imaging device 750 is toward the lower left, so incident light comes slanting from the lower left, especially when the camera lens aperture stop is open. With this structure, the ratio of incident light that is passed through the light-shielding film 752 and is incident on a photodiode 758 decreases toward pixels 754 in the upper right. Particularly when the aperture stop is open, the output value of each pixel 754 in monitor C changes more than in FIG. 4 and diminishes toward the upper right. This illustrates that there is a great deal of change between the lens being stopped down and stopped open. Therefore monitor pixel in this sexith embodiment have high sensitivity (amount of change in output value) to the degree of slant of incident light. The difference in output values (average output value) within monitor pixels is greater than in FIG. 4, as described above, and changes in the angle of incidence of incident light can be captured more efficiently.

FIG. 18(a) illustrates the luminance at the 3×3 pixels of block C when a first exemplary replaceable camera lens is installed. In this illustration, the camera lens has an incident light ray angle of incidence that is comparatively close to vertical (for example, Nikon's Nikkor 105 mm; F8). In contrast, FIG. 18(b) illustrates the luminance at the 3×3 pixels of block C for another replaceable camera lens, such as Nikon's Nikkor 50 mm; F1.4S, having a relatively short focal length, the aperture stop opened, and an incident light ray angle of incidence is slanted to the horizontal side.

Thus, when replaceable camera lenses with different focal lengths and F values are installed, and the aperture stops are different, different values (luminance) can be obtained for each pixel in block C. In FIG. 18(a) the average output is about 5.66 and the difference in output between the lower left pixel and the upper right pixel is 7. In FIG. 18(b) the average output is about 2.55, which is small, and the difference in output between the lower left pixel and the upper right pixel is 10, which is large.

### Seventh Embodiment

FIG. 19 illustrates a single lens reflex electronic camera 800 that may be equipped with any CCD 100, 300, 400, 500, or 600 of the first through fifth embodiments.

As shown in FIG. 19, the single lens reflex electronic camera 800 includes a camera body 810, finder device 820, and replaceable camera lens 830. Furthermore, in the example shown in the drawing, the first embodiment solid-state imaging device 100 is incorporated in the single lens reflex electronic camera 800.

The replaceable camera lens 830 includes an imaging lens 831, diaphragm 832, etc., inside it, and can be mounted on or removed from the camera body 810 at will. The camera body 810 is provided with a quick turn mirror 811, focal point detection device 812, and shutter 813. The solid-state imaging device (CCD) 100 is disposed to the rear of the shutter 813. Also, the finder device 820 is provided with a finder mat 821, pendaprism 822, eyepiece lens 823, prism 824, focusing lens 825, white balance sensor 235A, etc.

In the single lens reflex electronic camera 800 thus constituted, subject light L30 passes through the replaceable camera lens 830 and is incident at the camera body 810.

In this case, before release, the quick turn mirror 811 is at the location indicated by the broken line in the drawing, so some of the subject light L30 reflected by the quick turn mirror 811 is guided to the finder device 820 side and is focused by the finder mat 821. Part of the subject image obtained at this time is guided via the pendaprism 822 to the eyepiece lens 823, and the other part of the subject image passes through the prism 824 and focusing lens 825 and is incident at the white balance sensor 235A. This white balance sensor 235A detects the color temperature of the subject image. Also, part of the subject light L30 is reflected by an auxiliary mirror 811A that is integrated with the quick turn mirror 811 and is focused by the focal point detection device 812.

After release, the quick turn mirror 811 moves clockwise in the drawing (in the drawing, indicated by a solid line), and the subject light L30 is incident at the shutter 813 side.

Therefore, when taking a picture, matching of the focal point is first detected by the focal point detection device 812, and then the shutter 813 opens. As a result of this shutter 813 opening operation, the subject light L30 becomes incident at the solid-state imaging device (CCD) 100 and is focused at its light-receiving surface.

Having received the subject light L30 the solid-state imaging device (CCD) 100 generates an electric signal corresponding to the subject light L30 and performs various image signal processing such as white balance correction, etc., on this electric signal based on the signal from the white balance sensor 235A. After correction the image signal (RGB data) is output to a buffer memory (not shown in the drawing). Shading correction in this image signal processing is done to match the shading correction values obtained using the methods described in the first through fifth embodiments.

### Eighth Embodiment

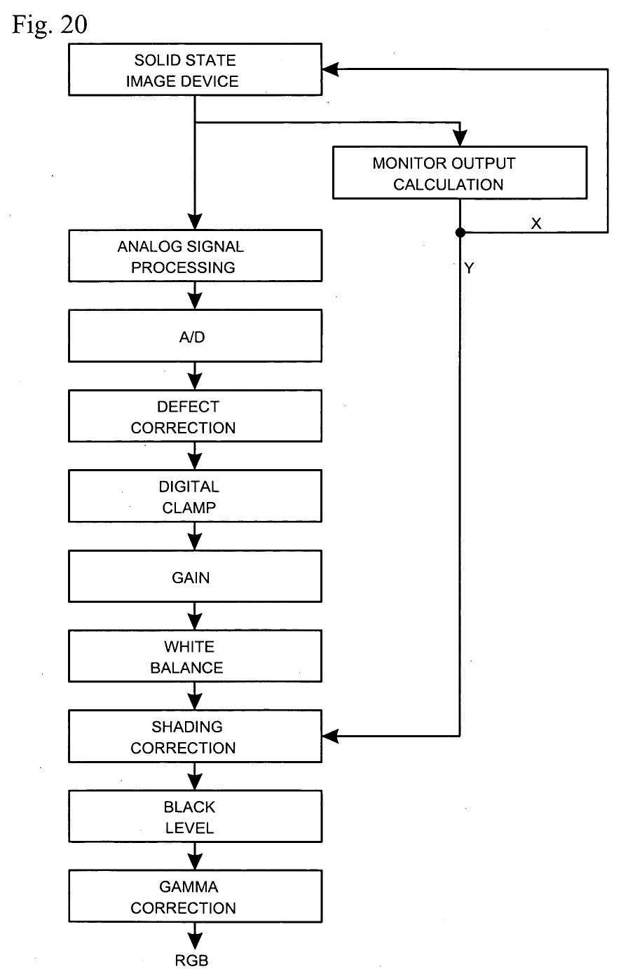

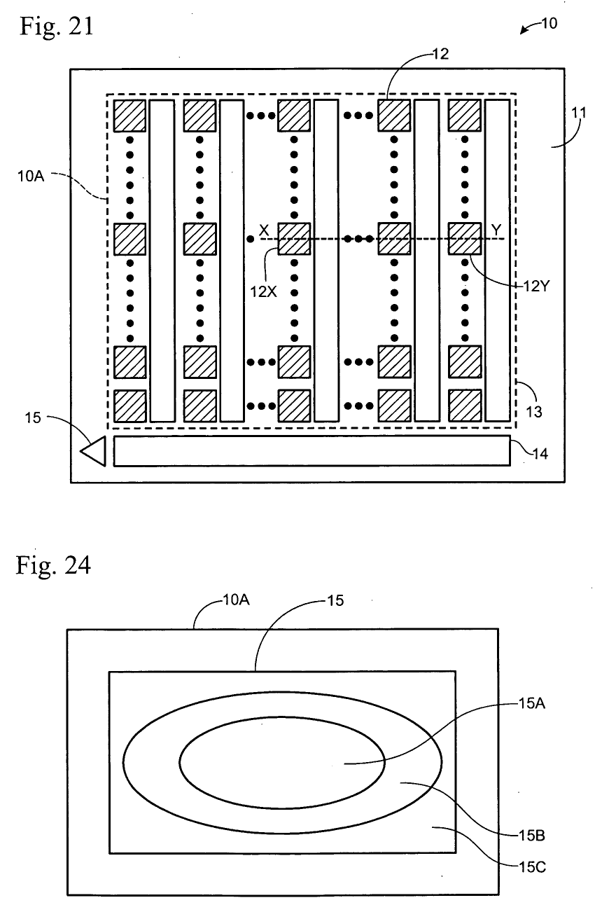

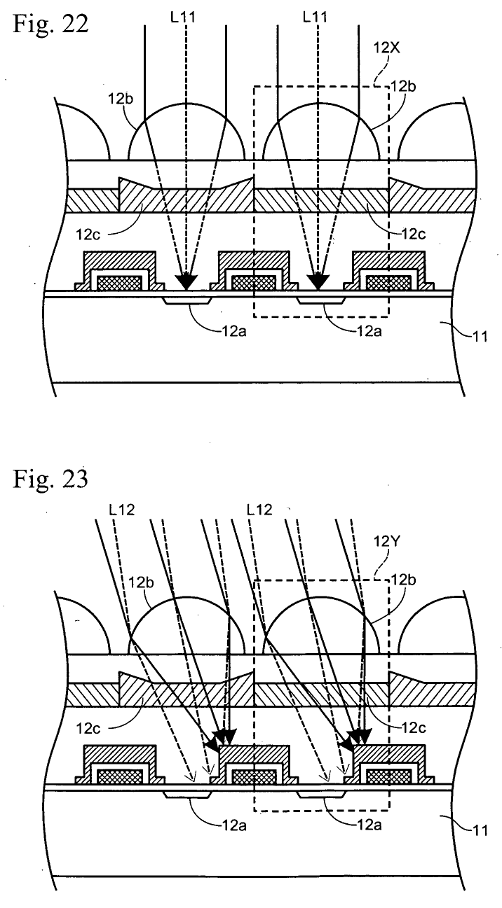

FIG. 20 shows an image processing flow chart for performing shading correction when any of the solid-state imaging devices 100, 300, 400, 500, or 600 of the first through fifth embodiments is used in an electronic camera.

As shown in this flow chart, first, luminance information is acquired on the monitor image in an electronic camera using the solid-state imaging device 100, 300, 400, 500, or 600 before taking the main picture. The luminance information undergoes simple calculations as illustrated.

If the electronic camera is one in which the solid-state imaging device 100, 300, 400, 500, or 600 has a transmissivity control means (for example, an EC control film) so that transmissivity can be controlled within a plane, feedback is applied to the electronic camera via the route indicated by X in FIG. 20 in order to control transmissivity within the region surface when taking a picture, and the imaging conditions are determined.

If the electronic camera does not have a transmissivity control means, the output signal (luminance information) from the pixels (130, 330 . . . ) of the available pixel parts (110B, 310B . . . ) is found simultaneously with taking a picture or immediately before taking a picture via the route indicated by Y in FIG. 20, and a correction value (multiplication factor) corresponding to that luminance information is compared to data written to a ROM as a correction table, thereby finding information pertaining to shading correction in situ and correcting the shading regardless of the replaceable camera lens type, stop value, lens pupil position, etc.

If high-precision correction is not required, it is also possible to not have a correction table in ROM and to calculate a correction value (coefficient) directly from the luminance information of the pixels (130, 330 . . . ) in the available pixel part (110B, 310B . . . ) and perform shading correction. In this case too a correction value (coefficient) can be found in situ corresponding to luminance information for each monitor pixel, and it becomes unnecessary to accommodate the individual differences, etc., between each and every camera lens.

As described above, a photoelectric conversion element may have two or more light detection parts that are disposed inside or outside the periphery of a light-receiving region and are capable of outputting a signal indicating the degree of shading. This allows luminance information indicating the degree of shading at the light-receiving region to be monitored, thereby allowing shading correction values to be found in situ.

Also, photoelectric conversion elements of pixels included in an available pixel part of the light-receiving region can be used as the light detection parts for obtaining luminance information indicating the degree of shading. This makes it possible to perform shading correction on image data obtained at the effective pixel part based on the signal from the available pixel part.

Furthermore, a first output part for reading output signals from pixels in the effective pixel part and a second output part for reading output signals from pixels in the available pixel part may be separately provided. This makes it possible to immediately obtain the data needed for finding the shading correction value.

In addition, a light-shielding film may be formed at the plane of incidence side of pixels in the available pixel part, and the centers of its apertures may be offset a distance that is predetermined for each pixel from the center of the relevant photoelectric conversion element, thereby allowing luminance information to be compared between pixels at the light detection part after light shielding by different patterns. This makes it possible to find where on the photodiodes (photoelectric conversion elements) light is incident, and from this result to find in situ a shading correction value.

Also, microlenses may be disposed in the available pixel part with optical axes that are offset by a fixed distance that is predetermined for each pixel from the center of the relevant photoelectric conversion element, thereby allowing luminance information to be compared between pixels at multiple light detection parts with different microlens positions. This makes it possible to find where on the photodiodes (photoelectric conversion elements) light is incident, and from this result to find in situ a shading correction value.

Furthermore, the luminance at a light detection part of pixels that have microlenses may be compared using as reference the luminance signal of a light detection part with pixels that do not have microlenses. This can provide a more accurate correction value.

In addition, the light detection part may output a signal indicating the degree of shading at a pixel where a specific color filter is disposed. This makes it possible to find a shading correction value corresponding to the characteristics of each color filter.

Also, an electronic camera can suitably determine the amount of correction while taking a picture based on the signal from the light detection part of a solid-state imaging device. As a result, it is not necessary to measure the shading correction value for each individual camera before shipment and write the correction to a ROM. This provides an electronic camera that is excellent in both cost and performance.

In view of the many possible embodiments to which the principles of this invention may be applied, it should be recognized that the detailed embodiments are illustrative only and should not be taken as limiting the scope of the invention. Rather, I claim as my invention all such embodiments as may come within the scope and spirit of the following claims and equivalents thereto.

1. A solid-state imaging device with a plurality of pixels having photoelectric conversion elements disposed in a light-receiving region, one or more of the photoelectric conversion elements being subject to a degree of shading from incident light, the improvement comprising:
two or more light detection parts disposed along the periphery of the light-receiving region, each light detection part being capable of outputting a signal corresponding the degree of shading.

2. The solid-state imaging device of claim 1 wherein the two or more light detection parts are disposed along and inside the periphery of the light-receiving region.

3. The solid-state imaging device of claim 1 wherein the two or more light detection parts are disposed along and outside the periphery of the light-receiving region.

4. The solid-state imaging device of claim 1 wherein:
the light-receiving region is divided into an effective pixel part, where output signals of the photoelectric conversion elements are used for image generation, and an available pixel part, where output signals of the photoelectric conversion elements are not used for image generation; and
the photoelectric conversion elements of the pixels included in available pixel part are used as the light detection parts.

5. The solid-state imaging device of claim 4 wherein a light-shielding film having plural specific apertures formed at a plane of incidence side of the available pixel part, each of plural ones of the specific apertures having a center that is offset from the corresponding photoelectric conversion element center by a fixed distance that is predetermined for that pixel.

6. The solid-state imaging device of claim 4 wherein:
a microlens is disposed at each pixel at a plane of incidence of the photoelectric conversion elements in the light-receiving region, each microlens having an optical axis, and
each of plural ones of the microlenses of the available pixel part is disposed so that its optical axis is offset from the corresponding photoelectric conversion element center by a fixed distance that is predetermined for that pixel.

7. The solid-state imaging device of claim 4 wherein:
plural types of color filters are disposed at plural pixels provided in the available pixel part; and
a signal is output from the light detection part indicating the degree of shading at a pixel where a specific color filter is disposed.

8. The solid-state imaging device of claim 4 further including a first output part for reading output signals from pixels in the effective pixel part and a separate second output part for reading output signals from pixels in the available pixel part.

9. The solid-state imaging device of claim 8 wherein:
plural types of color filters are disposed at plural pixels provided in the available pixel part; and
a signal is output from the light detection part indicating the degree of shading at a pixel where a specific color filter is disposed.

10. The solid-state imaging device of claim 8 wherein a light-shielding film having plural specific apertures formed at a plane of incidence side of the available pixel part, each of ones of the specific apertures having a center that is offset from the corresponding photoelectric conversion element center by a fixed distance that is predetermined for that pixel.

11. The solid-state imaging device of claim 10 wherein:
plural types of color filters are disposed at plural pixels provided in the available pixel part; and
a signal is output from the light detection part indicating the degree of shading at a pixel where a specific color filter is disposed.

12. The solid-state imaging device of claim 8 wherein:
a microlens is disposed at each pixel at a plane of incidence of the photoelectric conversion elements in the light-receiving region, each microlens having an optical axis, and
each of plural ones of the microlenses of the available pixel part is disposed so that its optical axis is offset from the corresponding photoelectric conversion element center by a fixed distance that is predetermined for that pixel.

13. The solid-state imaging device of claim 12 wherein:
plural types of color filters are disposed at plural pixels provided in the available pixel part; and
a signal is output from the light detection part indicating the degree of shading at a pixel where a specific color filter is disposed.

14. The solid-state imaging device of claim 12 further comprising a reference pixel that is included in the available pixel part and that does not have a microlens.

15. The solid-state imaging device of claim 13 wherein:
plural types of color filters are disposed at plural pixels provided in the available pixel part; and
a signal is output from the light detection part indicating the degree of shading at a pixel where a specific color filter is disposed.

16. An electronic camera, comprising:
a solid-state imaging device with a plurality of pixels having photoelectric conversion elements disposed in a light-receiving region, one or more of the photoelectric conversion elements being subject to a degree of shading, two or more light detection parts disposed along the periphery of the light-receiving region, each light detection part being capable of outputting a signal corresponding the degree of shading from incident light; and
an image adjustor for adjusting image data based on the signal corresponding to the degree of shading.

17. The electronic camera of claim 16 in which the electronic camera is of a replaceable lens type of single lens reflex electronic camera.

18. The electronic camera of claim 16 wherein:
the light-receiving region is divided into an effective pixel part, where output signals of the photoelectric conversion elements are used for image generation, and an available pixel part, where output signals of the photoelectric conversion elements are not used for image generation; and
the photoelectric conversion elements of the pixels included in available pixel part are used as the light detection parts.

19. The electronic camera of claim 18 in which the electronic camera is of a replaceable lens type of single lens reflex electronic camera.

20. The electronic camera of claim 18 wherein a light-shielding film having plural specific apertures formed at a plane of incidence side of the available pixel part, each of plural ones of the specific apertures having a center that is offset from the corresponding photoelectric conversion element center by a fixed distance that is predetermined for that pixel.

21. The electronic camera of claim 20 in which the electronic camera is of a replaceable lens type of single lens reflex electronic camera.

22. The electronic camera of claim 18 wherein:
a microlens is disposed at each pixel at a plane of incidence of the photoelectric conversion elements in the light-receiving region, each microlens having an optical axis, and
each of plural ones of the microlenses of the available pixel part is disposed so that its optical axis is offset from the corresponding photoelectric conversion element center by a fixed distance that is predetermined for that pixel.

23. The electronic camera of claim 22 in which the electronic camera is of a replaceable lens type of single lens reflex electronic camera.

24. The electronic camera of claim 18 wherein:
plural types of color filters are disposed at plural pixels provided in the available pixel part; and
a signal is output from the light detection part indicating the degree of shading at a pixel where a specific color filter is disposed.

25. The electronic camera of claim 24 in which the electronic camera is of a replaceable lens type of single lens reflex electronic camera.

26. The electronic camera of claim 18 further including a first output part for reading output signals from pixels in the effective pixel part and a separate second output part for reading output signals from pixels in the available pixel part.

27. The electronic camera of claim 26 in which the electronic camera is of a replaceable lens type of single lens reflex electronic camera.

28. The electronic camera of claim 26 wherein:
plural types of color filters are disposed at plural pixels provided in the available pixel part; and
a signal is output from the light detection part indicating the degree of shading at a pixel where a specific color filter is disposed.

29. The electronic camera of claim 26 wherein a light-shielding film having plural specific apertures formed at a plane of incidence side of the available pixel part, each of ones of the specific apertures having a center that is offset from the corresponding photoelectric conversion element center by a fixed distance that is predetermined for that pixel.

30. The electronic camera of claim 29 wherein:
plural types of color filters are disposed at plural pixels provided in the available pixel part; and
a signal is output from the light detection part indicating the degree of shading at a pixel where a specific color filter is disposed.

31. The electronic camera of claim 26 wherein:
a microlens is disposed at each pixel at a plane of incidence of the photoelectric conversion elements in the light-receiving region, each microlens having an optical axis, and
each of plural ones of the microlenses of the available pixel part is disposed so that its optical axis is offset from the corresponding photoelectric conversion element center by a fixed distance that is predetermined for that pixel.

32. The electronic camera of claim 31 wherein:
plural types of color filters are disposed at plural pixels provided in the available pixel part; and
a signal is output from the light detection part indicating the degree of shading at a pixel where a specific color filter is disposed.

33. The electronic camera of claim 31 further comprising a reference pixel that is included in the available pixel part and that does not have a microlens.

34. The electronic camera of claim 32 wherein:
plural types of color filters are disposed at plural pixels provided in the available pixel part; and
a signal is output from the light detection part indicating the degree of shading at a pixel where a specific color filter is disposed.

35. The electronic camera of claim 34 in which the electronic camera is of a replaceable lens type of single lens reflex electronic camera.

36. The electronic camera of claim 34 in which the two or more light detection parts are disposed along and inside the periphery of the light-receiving region.

37. The electronic camera of claim 34 in which the two or more light detection parts are disposed along and outside the periphery of the light-receiving region.

38. An in situ solid-state imaging device shading compensation method providing a shading compensation signal for a solid-state imaging device with a plurality of pixels having photoelectric conversion elements disposed in a light-receiving region, one or more of the photoelectric conversion elements being subject to a degree of shading from incident light, the method comprising:
obtaining an in situ output signal corresponding the degree of shading from each of two or more light detection parts disposed along the periphery of the light-receiving region, the light detection parts including photoelectric conversion elements of pixels that are not used for image generation.

39. The shading compensation method of claim 38 further comprising directing the incident light through plural specific apertures of a light-shielding film positioned at a plane of incidence side of the two or more light detection parts, each of plural ones of the specific apertures having a center that is offset from the corresponding photoelectric conversion element center by a fixed distance that is predetermined for that pixel.

40. The shading compensation method of claim 38 further comprising:
directing the incident light through a microlens disposed at each pixel at a plane of incidence of the photoelectric conversion elements in the light-receiving region, each microlens having an optical axis, and each of plural ones of the microlenses of the two or more light detection parts being disposed so that its optical axis is offset from the corresponding photoelectric conversion element center by a fixed distance that is predetermined for that pixel.

41. The shading compensation method of claim 38 wherein plural types of color filters are disposed at plural pixels provided in the two or more light detection parts, the method further comprising and outputting from the two or more light detection parts a signal indicating the degree of shading at a pixel where a specific color filter is disposed.

42. The shading compensation method of claim 38 further including providing output signals used for image generation from a first output and providing output signals not used for image generation from a second output separate from the first output.

43. The shading compensation method of claim 38 in which the two or more light detection parts are disposed along and inside the periphery of the light-receiving region.

44. The shading compensation method of claim 38 in which the two or more light detection parts are disposed along and outside the periphery of the light-receiving region.
